(19) United States
(12) Patent Application Publication
(10) Pub. No.: US 2011/0226305 A1
(43) Pub. Date: Sep. 22, 2011

(54) CONNECTION DEVICE FOR SOLAR CELL MODULE

(75) Inventors: Hsuan-Jui Chen, Tainan City (TW); Rung-Sheng Cheng, Tainan City (TW); Ray-Chien Lai, Longan Township (TW); Ching-Chieh Lin, Taipei City (TW)

(73) Assignees: Industrial Technology Research Institute, Zhudong Twonship (TW); a2peak Power Co., Ltd., Longtan Township (TW)

(21) Appl. No.: 12/725,741

(22) Filed: Mar. 17, 2010

(51) Int. Cl. H01L 31/042

(52) U.S. Cl. 136/244

(57) ABSTRACT

A connection device for a solar cell module is provided. The connection device comprises a pair of electrode elements electrically connected to the solar cell module, and a plurality of diodes electrically connected in parallel to the electrode elements. The connection device can avoid the reverse currents flowing into the solar cells.

### FIELD OF THE INVENTION

The present invention relates to a connection device, especially to a connection device for a solar cell module.

### BACKGROUND OF THE INVENTION

The photovoltaic energy conversion components are made by the PN semiconductor material, and can convert solar energy directly into electrical energy outputted. The outputted power of the solar cell panels can be affected by the sunlight intensity and the ambient temperature. Currently the types of the silicon solar cells in the market can be divided into the types of the single-crystal silicon, polysilicon and amorphous silicon. These three kinds of solar cells utilize almost the same principle of the photoelectric conversion. Due to the differences in the material structures, the different types of solar cells are developed.

Firstly, it is well known that the solar cell module is composed of solar cells, which are electrically connected in series and in parallel to provide the output with greater voltage and current. Since the solar cells adopt the electricity power devices with the PN junction semiconductor, when there is no sun light, the solar cells become just equivalent to diodes.

Secondly, usually in the practical uses of the solar cell modules, the solar cell modules are often electrically connected in series and in parallel according to the needs of the system so as to supply a larger load. However, in this condition, when a solar cell module is unevenly exposed to the sunlight or breaks down, significant damages to the system may occur.

Regarding uneven exposure to the sunlight, in the solar power system, since the solar cells must be installed outdoors, thus they are vulnerable to the influence or attacks from the environments, and various faults may occur. Among these faults, the partial shading fault is the most commonly seen fault occurred in the system. The so-called partial shading fault occurs, when a module or some cells in the solar power system are affected by the environment and result in the uneven sunlight exposure. There are several causes, e.g. the aging or damage of the cell, which may result in the occurrence of the breakdown problem.

Generally, the conventional way to avoid the occurrence of the above problem is performed by using a single diode connected in a single solar cell, or by using a single diode, so-called bypass diode, connected to several solar cells, so that when partial shading fault occur in some solar cells of the solar cell modules (or several solar cells are reversely biased), the single diode will be electrically conducted in order to avoid the reverse current flowing into the solar cell module and the resultant burning of the solar cells so as to attain the protecting effect.

In the market, generally when the solar cell module is applied, for example applied to the building-integrated photovoltaic (BIIPV) system, in order to output the electricity to the external electronic appliances, there is a connection device between two output cables of the solar cell module.

In the above, the connection device probably includes a hollow housing, two connection bases installed inside the housing and connected to the cables, two terminal bases embedded on the housing and connected to the connection bases to provide the electrical connection with the external electronic appliances, and a diode connected to the connection bases to prevent the reverse current flowing into the solar cells due to uneven solar radiation and being as a protection element. When the above components are assembled, a curable plastics is infused inside the housing to protect and to fix the terminal bases and to prevent the moisture attach to or oxidation on the cables inside the housing.

However, for the structural designs of the above connection devices, when the area of the solar cells in the solar cell module is larger, the more electrical currents will be generated. Accordingly, the dimension of the diode as a protection component becomes larger, and the electrode plates require the larger heat dissipation areas. Meanwhile, the original design of the connection device has to be changed, and consequently hard to be integrated into the BIPV system for the energy-saving buildings.

Therefore, due to the above mentioned drawback of the single diode as an electronic element for preventing the reverse current, a connection device applied to the solar cell module and able to be integrated into the building with the aesthetic design and the simple connection circuit is earnestly required.

### SUMMARY OF THE INVENTION

The present invention provides the connection device and the method for protecting a solar cell module. The system and the method of the present invention can effectively prevent the reverse electrical current flowing into the solar cells and the resultant burning of the solar cells.

In accordance with one aspect of the present invention, a connection device for a solar cell module is provided.

The above connection device comprises a pair of electrode elements electrically connected to the solar cell module; and a plurality of diodes electrically connected in parallel to the electrode elements.

In accordance with another aspect of the present invention, a method for protecting a solar cell module is provided.

The above method comprises steps of providing a plurality of diodes, and electrically connecting the diodes in parallel to the solar cell module.

In accordance with a further aspect of the present invention, a connection device for a solar cell module is provided.

The above connection device comprises a plurality of protecting elements electrically connected in parallel to the solar cell module.

The above connection device further comprises a pair of electrode elements, wherein the solar cell module include a plurality of solar cells, and the protecting elements include diodes electrically connected to the solar cells through the electrode elements.

In the above connection device, the electrode elements are made of a material being one of a metal and an alloy.

The above connection device further comprises a housing connected to the solar cell module, wherein the electrode elements and the diodes are disposed inside the housing.

The above connection device further comprises a ribbon, wherein the housing is connected to the solar cell module through the ribbon.

In the above connection device, the ribbon is made of a material being one of a metal and an alloy.

The above connection device further comprises at least two connection cords electrically connected to the electrode elements, respectively, wherein the housing has an opening, the solar cell module generates an electricity, and the connection cords extend through the opening and outputs the electricity to a load.

In the above connection device, each of the electrode elements comprises a plurality of contact pads, each of the diodes has a cathode and an anode, and the cathodes and the anodes of the diodes are electrically connected to the contact pads.

In the above connection device, the cathodes of the diodes are electrically connected to the contact pads of one of the electrode elements, and the anodes of the diodes are electrically connected to the contact pads of another one of the electrode elements.

In the above connection device, the diodes comprise Schottky diodes.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is the schematic diagram showing a circuit of the solar cell module composed of several solar cells connected in series in the present invention;

FIG. 2a is the schematic diagram showing a profile of the connection device applied to the solar cell module in the present invention;

FIG. 2b is the schematic diagram showing diodes electrically connected to the electrode plates in the present invention;

FIG. 3 is the schematic diagram showing at least two by-pass diodes electrically connected in parallel to the output terminals of the solar cells in the present invention; and

FIG. 4 is the schematic diagram showing a profile of another connection device applied to the solar cell module in the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

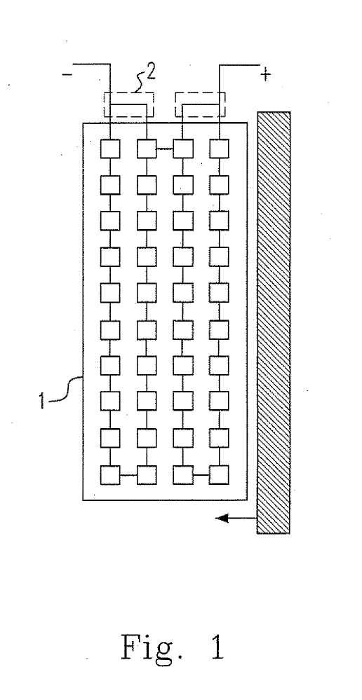

For overcoming the drawback of the above-mentioned single diode to avoid the reverse current, a new connection device applied to the solar cell module as shown in FIG. 1 is proposed in the present invention. In FIG. 1, the solar cell module is composed of several solar cells electrically connected in series to provide the output with larger voltage and current.

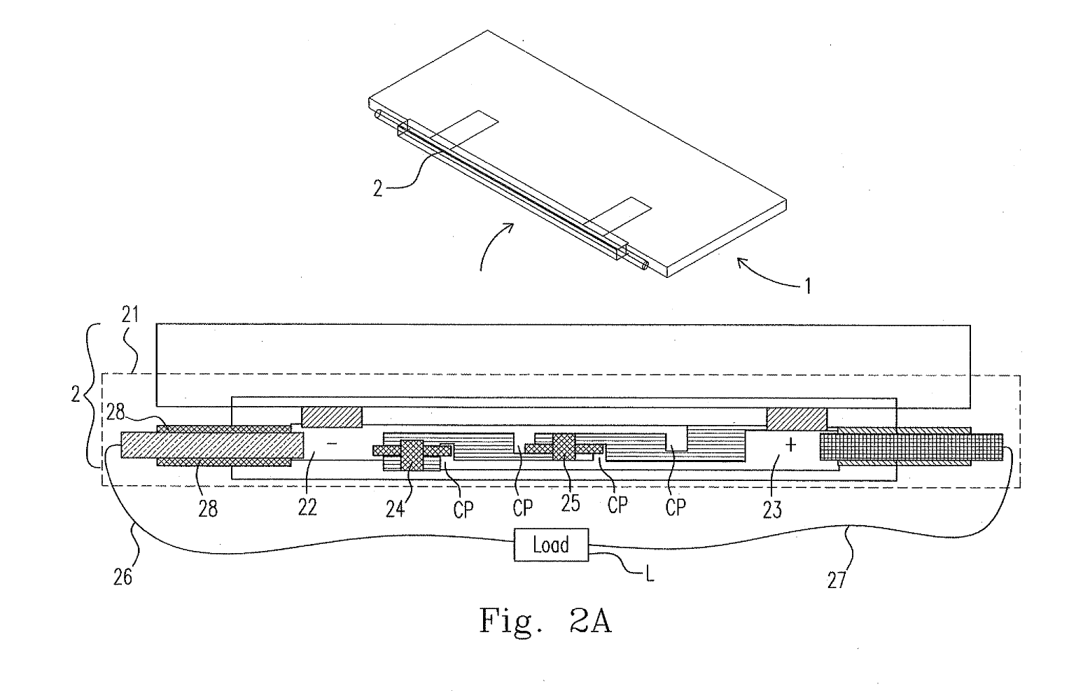

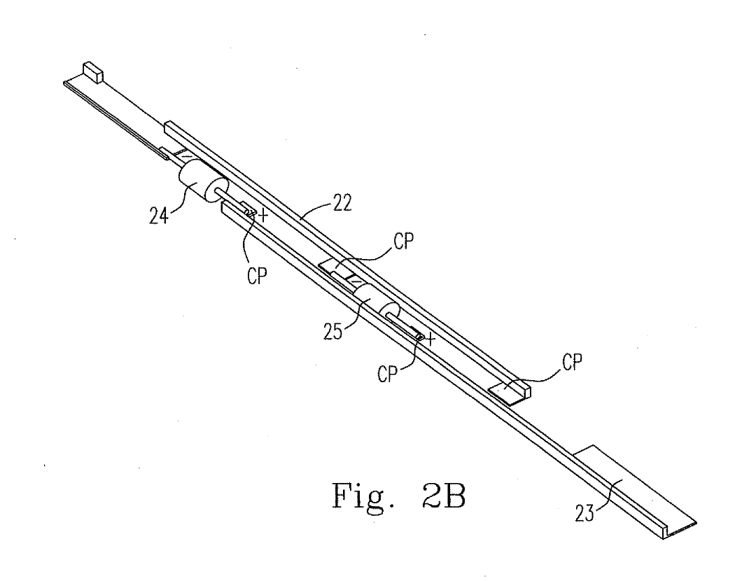

Please refer to FIG. 2a, which is the schematic diagram showing a profile of the connection device applied to the solar cell module in the present invention. In FIG. 2a, the connection device 2 includes a housing 21 with at least one opening, two electrode elements (plates) 22 and 23 with plural contact pads, at least two diodes 24 and 25, and the circuit inside the connection device 2.

In the above, the appearance of the connection device 2 is designed as a long rectangular housing with an inner space to accommodate the above mentioned electronic elements. Due to the appearance of the long rectangular shape, the connection device 2 has small volume and good integrability, and can be easily combined at the lateral side of the solar cell module 1.

The two electrode elements 22 and 23, each of which has plural contact pads are configured inside the housing, and is electrically connected to the solar cells inside the solar cell module. It can be clearly seen from FIG. 2a that the contact pads have flat surfaces, which can be electrically connected to other electronic elements. The two electrode elements 22 and 23 can be made of metal or alloy. In this embodiment, they are made of copper or aluminum as a typical example.

The anode terminals of the two diodes (protecting elements) 24 and 25 electrically connected in parallel and configured inside the housing 21 are electrically connected to the same side of the contact pad of the second electrode element 23. As referring to FIG. 2b, the anode terminal of the first diode 24 is electrically connected to the upper surface of the second electrode element 23; while the anode terminal of the second diode 25 is also electrically connected to the upper surface of the second electrode element 23. However, regarding the quantity of the diodes used in the solar cell module 1 composed of several solar cells electrically connected in series, as referring to FIG. 1, one connection device 2 is electrically connected in parallel to a set of twenty solar cells, which are electrically connected in series. Based on the same way, when the solar cell module 1 contains more than forty solar cells, then a third connection device or more connection devices will be electrically connected in parallel to the solar cells.

Furthermore, Schottky diodes are adopted in the present embodiment as the protecting electronic elements to prevent the reverse currents. The Schottky diodes electrically connected to the solar cells have low forward voltage drop and fast switching capability, so when a part of the solar cells has partial shading fault, e.g. when several solar cells are reverse biased, the Schottky diodes will be electrically conducted in order to avoid the reverse current flowing into the solar cell module and the resultant burning of the solar cells so as to reach the protecting effect.

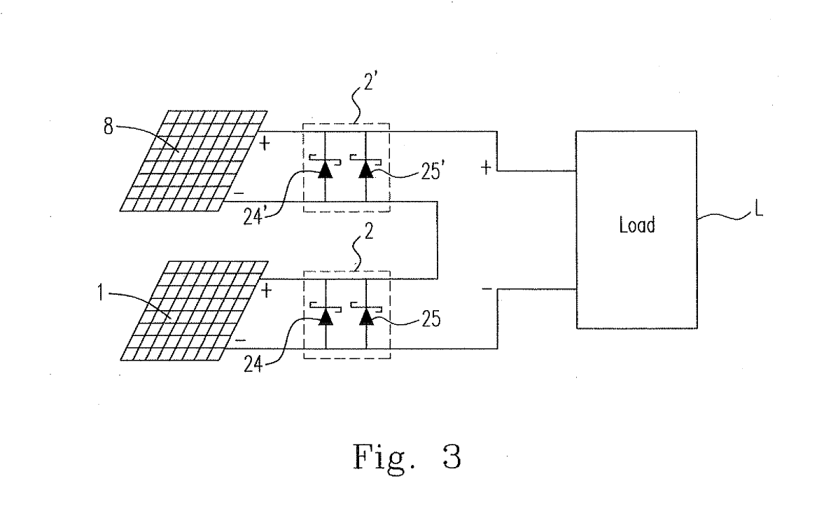

The circuit of the two Schottky diodes 24 and 25 electrically connected in parallel inside the connection device 2 is shown in FIG. 3. It can be seen from FIG. 3 that the cathode and anode terminals of the first Schottky diode 24 are electrically connected to the positive and negative terminals of the solar cell module 1, respectively; while the cathode and anode terminals of the second Schottky diode 25 are also electrically connected to the positive and negative terminals of the solar cell module 1, respectively.

Similarly, the other two Schottky diodes 24′ and 25′ inside the other connection device 2′ are electrically connected in parallel to the other solar cell module 8 as shown in FIG. 3. It can be seen from FIG. 3 that the cathode and anode terminals of the third Schottky diode 24′ are electrically connected to the positive and negative terminals of the solar cell module 8, respectively; while the cathode and anode terminals of the fourth Schottky diode 25′ are also electrically connected to the positive and negative terminals of the solar cell module 8, respectively.

As different from the single diode used in the conventional connection device, where the larger diode is required when larger current flows through this single diode, the present invention adopts plural diodes electrically connected in parallel, and thus does not require a larger diode. Moreover, the method of the parallel electrical connections for the diodes in the present invention can reduce the electrical current flowing through the diode, and thus not only can solve the problem of the burning of the diode under high temperature, but also can enhance the potentials of the BIPV applications.

The housing 21 of the connection device 2 installed on the BIPV system can further include a first cable (or connection cord) 26 and a second cable (or connection cord) 27, which are electrically connected to the first electrode element 22 and the second electrode element 23, respectively. The cables 26 and 27 can extend outwardly from at least one opening of the housing 21 (in this embodiment, the cables 26 and 27 extend from two opening of the housing 21) so as to output the electricity generated by the solar cell module 1 to a load L for supplying the electricity.

After the above-mentioned components have been installed, a curable plastic can be optionally infused inside the housing in order to form a first protecting layer 28 on the two cables 26 and 27 so as to protect and to fix the cables 26 and 27, and to prevent the moisture attach to or oxidation on the circuit inside the housing 21.

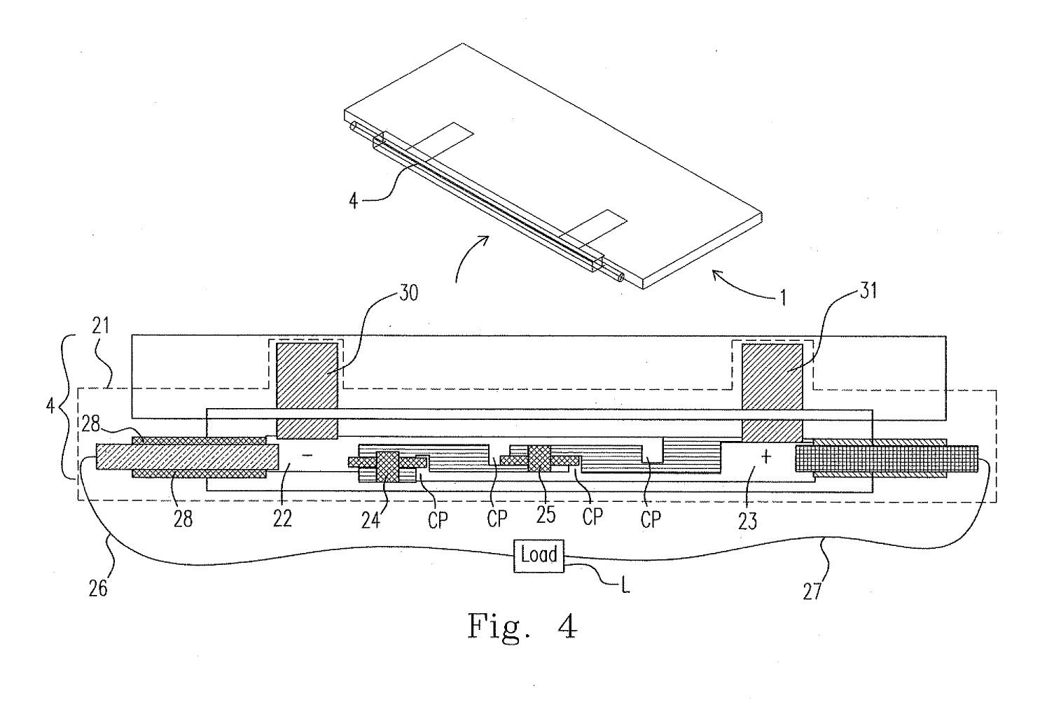

Regarding another embodiment of the connection devices, the present invention proposes another connection device connected with the solar cells inside the solar cell module, as shown in FIG. 4. The FIG. 4 is based on FIG. 2, and shows the profile of another connection device applied to the solar cell module in the present invention. It can be seen from FIG. 4 that the first connection element 30 and the second connection element 31 are disposed between the connection device 4 and the solar cells inside the solar cell module. It can be understood that the first and the second connection elements 30 and 31 connected with the connection device 4 are electrically conductive devices for connecting multiple electronic components or circuits. In this embodiment, the connection elements 30 and 31 are made of metal or alloy. As a typical example, the connection elements 30 and 31 can be a first and a second ribbons 30 and 31, which are made of the copper foils plated with tin.

One end of the first ribbon 30 is electrically connected to the first electrode element 22, and the other end of the first ribbon 30 is electrically connected to the solar cells inside the solar cell module 1. One end of the second ribbon 31 is electrically connected to the second electrode element 23, and the other end of the second ribbon 31 is electrically connected to the solar cells inside the solar cell module 1.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A connection device for a solar cell module, comprising:
a pair of electrode elements electrically connected to the solar cell module; and
a plurality of diodes electrically connected in parallel to the electrode elements.

2. The connection device of claim 1, further comprising a housing connected to the solar cell module, wherein the electrode elements and the diodes are disposed inside the housing.

3. The connection device of claim 2, further comprising a ribbon, wherein the housing is connected to the solar cell module through the ribbon made of a material being one of a metal and an alloy.

4. The connection device of claim 2, further comprising at least two connection cords electrically connected to the electrode elements, respectively, wherein the housing has an opening, the solar cell module generates an electricity, and the connection cords extend through the opening and output the electricity to a load

5. The connection device of claim 1, wherein the solar cell module comprises a plurality of solar cells, and the electrode elements are electrically connected to the solar cells and are made of a material being one of a metal and an alloy.

6. The connection device of claim 1, wherein each of the electrode elements comprises a plurality of contact pads, each of the diodes has a cathode and an anode, and the cathodes and the anodes of the diodes are electrically connected to the contact pads.

7. The connection device of claim 5, wherein the cathodes of the diodes are electrically connected to the contact pads of one of the electrode elements, and the anodes of the diodes are electrically connected to the contact pads of another one of the electrode elements.

8. The connection device of claim 1, wherein the diodes comprise Schottky diodes.

9. A method for protecting a solar cell module, comprising steps of:
providing a plurality of diodes; and
electrically connecting the diodes in parallel to the solar cell module.

10. The protecting method of claim 9, wherein the solar cell module comprises a plurality of solar cells, and the diodes comprise Schottky diodes.

11. A connection device for a solar cell module, comprising:
a plurality of protecting elements electrically connected in parallel to the solar cell module.

12. The connection device of claim 11, further comprising a pair of electrode elements, wherein the solar cell module include a plurality of solar cells, and the protecting elements include diodes electrically connected to the solar cells through the electrode elements.

13. The connection device of claim 12, wherein the electrode elements are made of a material being one of a metal and an alloy.

14. The connection device of claim 12, further comprising a housing connected to the solar cell module, wherein the electrode elements and the diodes are disposed inside the housing.

15. The connection device of claim 14, further comprising a ribbon, wherein the housing is connected to the solar cell module through the ribbon.

16. The connection device of claim 15, wherein the ribbon is made of a material being one of a metal and an alloy.

17. The connection device of claim 14, further comprising at least two connection cords electrically connected to the electrode elements, respectively, wherein the housing has an opening, the solar cell module generates an electricity, and the connection cords extend through the opening and outputs the electricity to a load.

18. The connection device of claim 12, wherein each of the electrode elements comprises a plurality of contact pads, each of the diodes has a cathode and an anode, and the cathodes and the anodes of the diodes are electrically connected to the contact pads.

19. The connection device of claim 18, wherein the cathodes of the diodes are electrically connected to the contact pads of one of the electrode elements, and the anodes of the diodes are electrically connected to the contact pads of another one of the electrode elements.

20. The connection device of claim 12, wherein the diodes comprise Schottky diodes.
